(19) United States
(12) Patent Application Publication
(10) Pub. No.: US 2006/0110882 A1
(43) Pub. Date: May 25, 2006

(54) METHODS OF FORMING GATE STRUCTURE AND FLASH MEMORY HAVING THE SAME

(76) Inventors: Chen-Chiang Liu, Hsinchu City (TW); Da Sung, Hsinchu City (TW); Hsin-Ying Tung, Taichung County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/162,533

(22) Filed: Sep. 14, 2005

(30) Foreign Application Priority Data
Nov. 19, 2004 (TW) 93135542

(51) Int. Cl. H01L 21/336

(52) U.S. Cl. 438/257; 438/265

(57) ABSTRACT

A method of forming a gate structure, including forming sequentially a gate dielectric layer, a conductive layer, a protective layer, a sacrificial layer, and a patterned mask layer over a substrate. The exposed sacrificial layer is removed by using the patterned mask layer as an etching mask and the protective layer as an etching stop layer. Spacers are formed on the sidewalls of the sacrificial layer. Subsequently, the exposed protective layer and the conductive layer are removed by using the spacers and the sacrificial layer as etching masks, so as to form gate structures. By forming the protective layer on the conductive layer, the present invention can avoid the top surface of each gate structure from generating sharp corners and also increase the width of each gate structure.

### CROSS-REFERENCE TO RELATED APPLICATION

This application claims the priority benefit of Taiwan application serial no. 93135542, filed on Nov. 19, 2004. All disclosure of the Taiwan application is incorporated herein by reference.

### BACKGROUND OF THE INVENTION

1. Field of the Invention

The present invention generally relates to a method of forming a semiconductor device. More particularly, the present invention relates to a method for forming a gate structure and the flash memory having the same.

2. Description of Related Art

As the semiconductor device become minimized, it is important to increase the integration of the device. In general, the critical dimension of the semiconductor device is limited by the resolution of photolithography technologies. Since the resolution of photolithography processes is determined by the wavelength of the light source, the pitch of the pattern for the semiconductor device is accordingly restricted. If the pitch of the pattern is smaller than the wavelength of the light source, it is difficult to precisely define the pattern.

In order to solve such problems, a process for increasing the width of the gate and reducing the distance between the gates is proposed.

FIGS. 1A to 1E are cross-sectional views of the fabrication process steps for a prior art floating gate with increased width. Referring to FIG. 1A, a substrate having an isolation structure 102 is provided and a tunneling oxide layer 104 is formed over the substrate 100. a polysilicon layer 106 and a first silicon nitride layer 108 are sequentially formed over the tunneling oxide layer 104. Then, a patterned resist layer 110 is formed on the first silicon nitride layer 108 and a portion of the first silicon nitride layer 108 is exposed.

Referring to FIG. 1B, using the patterned resist layer 110 as the etching mask, the exposed silicon nitride layer 108 is removed. Afterwards, the patterned resist layer 110 is removed. Because the etching selectivity between the first silicon nitride layer 108 and the polysilicon layer 106 is not large, recesses 120 may be formed on the surface of the polysilicon layer 106.

Referring to FIG. 1C, a second silicon nitride layer 112 is formed over the substrate 100, covering the first silicon nitride layer 108.

As shown in FIG. 1D, etching back the second silicon nitride layer 112 to form spacers 112a on sidewalls of the first silicon nitride layer 108. Then, by using the spacers 112a and the first silicon nitride layer 108 as etching masks, the polysilicon layer 106 is etched until the tunneling oxide layer 104 is exposed and the polysilicon floating gate 106a is formed.

As shown in FIG. 1E, the spacers 112a and the first silicon nitride layer 108 are removed by, for example, wet etching by using hot phosphoric acid. However, as recesses 120 may be formed on the surface of the polysilicon layer 106 during the step of FIG. 1B, sharp corners 130 may be formed on the top surface of the polysilicon floating gate 106a. The sharp corners 130 can cause current leakage due to point discharge effects and result in errors in the memory operation.

In addition, the polysilicon floating gate 106a obtained after wet etching usually has rough surfaces (as shown in FIG. 2). FIG. 2 is a partial expanded view of the portion 11 of FIG. 1E. During wet etching, hot phosphoric acid will etch the surface 200 of the polysilicon floating gate 106a along the grain boundary of polysilicon, which will cause surface roughness.

For solving the above problems, a chemical mechanical polishing (CMP) process is performed in the prior art after the step of FIG. 1E, in order to planarize the surface of the polysilicon floating gate 106a. However, the extra CMP process leads to higher costs for the manufacture process and makes the manufacture process more complicated.

### SUMMARY OF THE INVENTION

Accordingly, the present invention is directed to a method for forming a gate structure, which can increase the width of the gate structure without performing a planarization process after forming the gate structure, under the controlled resolution of photolithography.

The present invention is directed to a method for forming a flash memory, which can increase the width of the gate structure and avoid sharp corners being formed on the gate structure without performing a planarization process after forming the gate structure, under the controlled resolution of photolithography.

According to an embodiment of the present invention, the present invention provides a method for forming a gate, comprising the steps of: providing a substrate having a gate dielectric layer thereon; forming a conductive layer on the gate dielectric layer; forming a protective layer on the conductive layer; forming a sacrificial layer over the protective layer; forming a patterned mask layer over the sacrificial layer, exposing a portion of the sacrificial layer; removing the exposed sacrificial layer by using the patterned mask layer as an etching mask and the protective layer as an etching stop layer; removing the patterned mask layer; forming a plurality of spacers on sidewalls of the sacrificial layer; removing a portion of the protective layer and a portion of the conductive layer by using the spacers and the sacrificial layer as etching masks; removing the spacers and the sacrificial layer; and removing the protective layer.

The gate structure fabricated according to this invention can further be applied in memory structures, for example, flash memory structures.

The methods of the present invention can prevent sharp corners being generated on the top surface of the gate structure by forming a protective layer between the conductive layer and the sacrificial layer to protect the underlying conductive layer and increase the width of the gate structure by forming spacers, under the controlled resolution of photolithography. Due to the protective layer, corrosion of etchants during the etching process to the surface of the conductive layer can be avoided, without the need of using the extra planarization process.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A to 1E are cross-sectional views of the fabrication process steps for a prior art floating gate with increased width.

FIG. 2 is a partial expanded view of the portion II of FIG. 1E.

FIGS. 3A to 3F are cross-sectional views of the fabrication process steps for a gate structure according to one preferred embodiment of this invention.

FIGS. 4A to 4C are cross-sectional views of the fabrication process steps for a flash memory according to another preferred embodiment of this invention.

FIG. 5 is the top view of FIG. 4C.

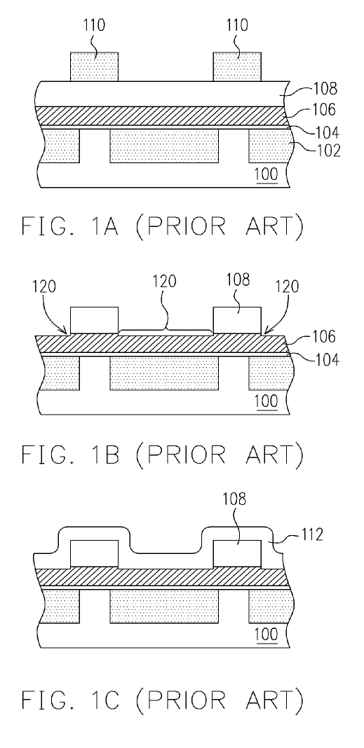

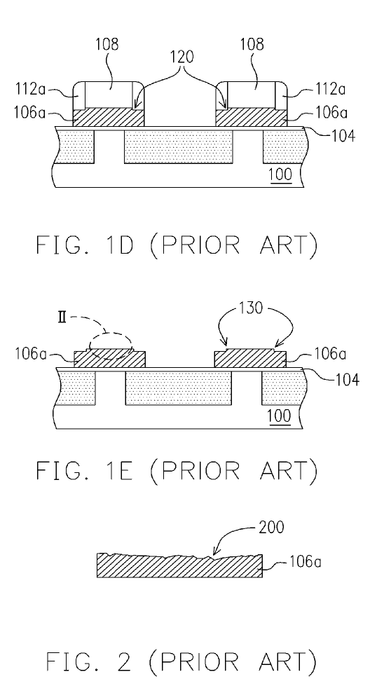

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

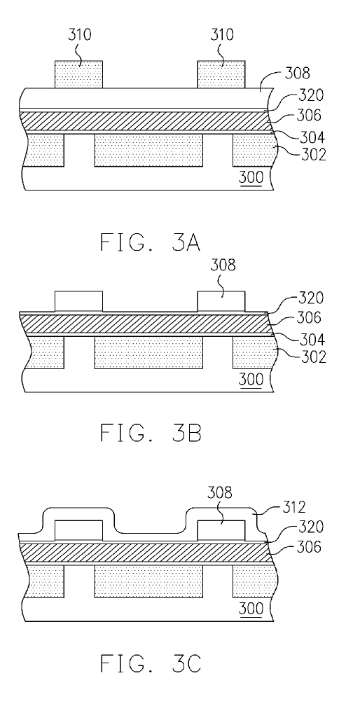

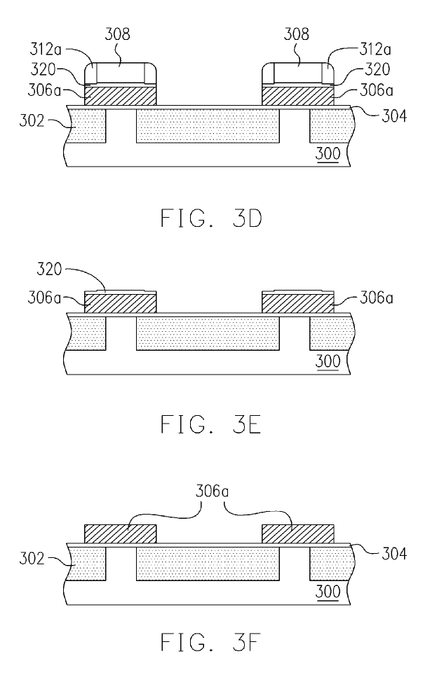

FIGS. 3A to 3F are cross-sectional views of the fabrication process steps for a gate structure according to one preferred embodiment of this invention. Referring to FIG. 3A, a substrate 300 having a gate dielectric layer 304 and at least an isolation structure 302 is provided. The isolation structure 302 is a shallow trench isolation (STI) structure, for example. A conductive layer 306 is formed on the gate dielectric layer 304. The material of the conductive layer 306 is polysilicon or other suitable materials, for example. Then, a protective layer 320 is formed over the conductive layer 306. For example, the protective layer 320 is a silicon oxide layer formed by, low temperature chemical vapor deposition (LPCVD) using TEOS as the reaction gas source. A sacrificial layer 308 is formed on the protective layer 320. The material of the sacrificial layer 308 is, for example, silicon nitride or other materials different from that of the protective layer 320 (such as polysilicon). For example, if the sacrificial layer 308 has a thickness of about 700 Angstroms, the protective layer 320 has a thickness of about 100 Angstroms. Next, a patterned mask layer 310, for example, a patterned resist layer, is formed over the sacrificial layer 308, exposing a portion of the surface of the sacrificial layer 308.

Referring to FIG. 3B, using the patterned mask layer 310 (shown in FIG. 3A) as an etching mask and the protective layer 320 as an etching stop layer, the exposed sacrificial layer 308 is removed by etching. The patterned mask layer 310 is then removed.

As shown in FIG. 3C, a insulating layer 312 is formed over the substrate 100 covering the sacrificial layer 308. The material of the insulating layer 312 is, for example, silicon nitride or other materials having high etching selectivity relative to the material of the conductive layer 306.

Referring to FIG. 3D, etching back the insulating layer 312 until a portion of the protective layer 320 is exposed, and spacers 312a are formed on sidewalls of the sacrificial layer 308. Later on, using the spacers 312a and the sacrificial layer 308 as etching masks, a portion of the protective layer 320 and a portion of the conductive layer 306 are removed until the gate dielectric layer 304 is exposed, so as to form the gate structures 306a. The width of the gate structure 306a can be increased by forming the spacers 312a, instead of being restricted by the photolithography processes. That is, the pitch (distance) between the gate structures 306a can be smaller than the smallest distance of the photolithography processes.

Referring to FIG. 3E, the spacers 312a and the sacrificial layer 308 are removed by, for example, wet etching. If the spacers 312a and the sacrificial layer 308 are made of silicon nitride, hot phosphoric acid can be used in the wet etching process. Because the gate structure 306a is protected by the protective layer 320, the top surface of the gate structure 306a will not be corroded by hot phosphoric acid.

As shown in FIG. 3F, the protective layer 320 is removed and the gate structure 306a having a smooth top surface is obtained.

Accordingly, the method for manufacturing the gate structure can also be applied for the fabrication of the flash memory structure.

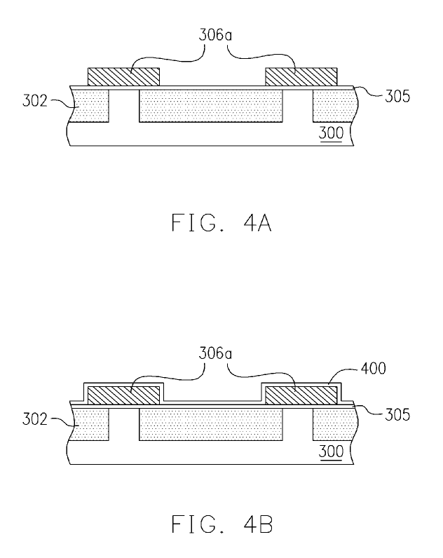

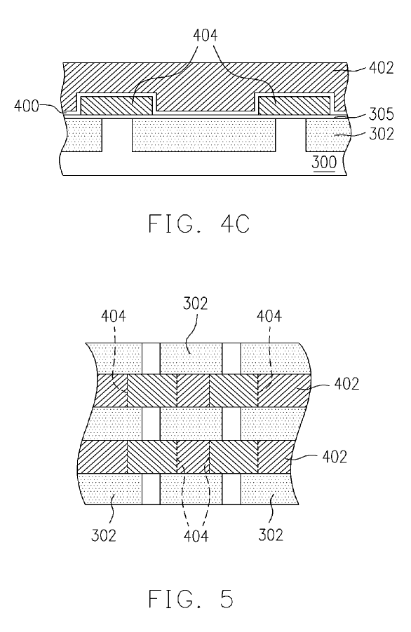

FIGS. 4A to 4C are cross-sectional views of the fabrication process steps for a flash memory according to another preferred embodiment of this invention.

The same reference number used in FIG. 3F will be used again for the same element in this embodiment. Referring to FIG. 4A, a tunneling oxide layer 305 and strip conductive layers 306a are formed over the substrate 300 having the isolation structure 302. The tunneling oxide layer 305 is formed on the substrate 300, instead of forming the gate dielectric layer 304. The steps of forming strip conductive layers 306a (i.e. gate structures 306a of FIG. 3F) can be referred to the steps shown in FIGS. 3A-3F.

Referring to FIG. 4B, an inter-gate dielectric layer 400 is formed over the substrate 300 and covers the surfaces of the strip conductive layers 306a. The inter-gate dielectric layer 400 is, for example, a stacked structure of silicon oxide/silicon oxide/silicon nitride layers or of silicon oxide/silicon nitride/silicon oxide layers.

Referring to FIG. 4C, a conductive layer 402 is formed over the substrate 300, covering the inter-gate dielectric layer 400. The conductive layer 402 is a doped polysilicon layer, for example. Afterwards, the conductive layer 402, the inter-gate dielectric layer 400 and the strip conductive layers 306a are patterned, so as to form a plurality of control gates 402 (in strip shapes) and a plurality of floating gates 404 (in block shapes), as shown in FIG. 5 (FIG. 5 is the top view of FIG. 4C).

Referring to both FIGS. 4C and 5, the control gates 402 and the floating gates 404 are formed over the substrate 300, while the inter-gate dielectric layer 400 is formed between the control gates 402 and the floating gates 404. As described above, no sharp corners are generated on the surface of the resultant gate structures 306a (later becoming the floating gates 404 after patterned). Therefore, leakage current due to point discharge effects in the prior art can be prevented.

In conclusion, the present invention has at least the following advantages:

1. By forming a protective layer between the conductive layer and the sacrificial layer to protect the underlying conductive layer, it can prevent sharp corners being generated on the top surface of the gate structure.

2. The present invention can increase the width of the gate structure by forming spacers, under the controlled resolution of photolithography.

3. Due to the protective layer, corrosion of etchants (such as, hot phosphoric acid) to the surface of the conductive layer (for example, the polysilicon layer) can be avoided, without the need of using the extra planarization process.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for forming a gate, comprising:
providing a substrate having a gate dielectric layer thereon;
forming a conductive layer on the gate dielectric layer;
forming a protective layer on the conductive layer;
forming a sacrificial layer over the protective layer;
forming a patterned mask layer over the sacrificial layer, exposing a portion of the sacrificial layer;
removing the exposed sacrificial layer by using the patterned mask layer as an etching mask and the protective layer as an etching stop layer;
removing the patterned mask layer;
forming a plurality of spacers on sidewalls of the sacrificial layer;
removing a portion of the protective layer and a portion of the conductive layer by using the spacers and the sacrificial layer as etching masks;
removing the spacers and the sacrificial layer; and removing the protective layer.

2. The method according to claim 1, wherein the protective layer includes a silicon oxide layer.

3. The method according to claim 2, wherein a method for forming the protective layer includes LPCVD.

4. The method according to claim 1, wherein the step of forming the plurality of spacers comprises:
forming a insulating layer over the substrate covering the sacrificial layer; and
etching back the insulating layer until a portion of the protective layer is exposed.

5. The method according to claim 4, wherein the insulating layer includes a silicon nitride layer.

6. The method according to claim 1, wherein the sacrificial layer comprises a silicon nitride layer.

7. The method according to claim 1, wherein a method for removing the spacers and the sacrificial layer includes a wet etching method.

8. The method according to claim 7, wherein the wet etching method includes using hot phosphoric acid.

9. The method according to claim 1, wherein a method for removing the protective layer includes wet etching.

10. The method according to claim 1, wherein the conductive layer comprises a doped polysilicon layer.

11. A method for forming a flash memory, comprising:
providing a substrate having a tunnelling oxide layer thereon;
forming a first conductive layer on the tunnelling oxide layer;
forming a protective layer on the first conductive layer;
forming a sacrificial layer over the protective layer;
forming a patterned mask layer over the sacrificial layer, exposing a portion of the sacrificial layer;
removing the exposed sacrificial layer by using the patterned mask layer as an etching mask and the protective layer as an etching stop layer;
removing the patterned mask layer;
forming a plurality of spacers on sidewalls of the sacrificial layer;
removing a portion of the protective layer and a portion of the first conductive layer by using the spacers and the sacrificial layer as etching masks, so as to form a plurality of strip conductive layers;
removing the spacers and the sacrificial layer;
removing the protective layer;
forming an inter-gate dielectric layer covering surfaces of the plurality of strip conductive layers;
forming a second conductive layer over the substrate covering the inter-gate dielectric layer; and
patterning the second conductive layer, the inter-gate dielectric layer and the plurality of strip conductive layers, so as to form a plurality of control gates and a plurality of floating gates.

12. The method according to claim 11, wherein the protective layer includes a silicon oxide layer.

13. The method according to claim 12, wherein a method for forming the protective layer includes LPCVD.

14. The method according to claim 11, wherein the step of forming the plurality of spacers comprises:
forming a insulating layer over the substrate covering the sacrificial layer; and
etching back the insulating layer until a portion of the protective layer is exposed.

15. The method according to claim 14, wherein the insulating layer includes a silicon nitride layer.

16. The method according to claim 11, wherein the sacrificial layer comprises a silicon nitride layer.

17. The method according to claim 11, wherein a method for removing the spacers and the sacrificial layer includes a wet etching method.

18. The method according to claim 17, wherein the wet etching method includes using hot phosphoric acid.

19. The method according to claim 11, wherein a method for removing the protective layer includes a wet etching method.

20. The method according to claim 11, wherein the first conductive layer comprises a doped polysilicon layer and the second conductive layer comprises a doped polysilicon layer.
